(19) United States
(12) Patent Application Publication
(10) Pub. No.: US 2009/0040076 A1
(43) Pub. Date: Feb. 12, 2009

(54) Character Arrangement Method and Character Input Device

(76) Inventor: Ye-Eun Kim, Won-Joo Si (KR)

Correspondence Address: Invent Capture, LLC, 3319 Foxtail Terrace, Fremont, CA, 94536, US

(21) Appl. No.: 12/027,962

(22) Filed: Feb. 7, 2008

(30) Foreign Application Priority Data
Aug. 8, 2007 (KR) 10-2007-0079371

(51) Int. Cl. H03K 17/79; H03M 11/00

(52) U.S. Cl. 341/22

(57) ABSTRACT

The present invention relates to a character arrangement method and a character input method in an electronic device. A telephone-style keypad is assigned symbolic word representations to provide a heuristic and intuitive text input interface to a user. The symbolic word representations on at least some keys on the keypad can create multiple numbers of same alphabets, which can be utilized for easier text entry of frequently-used alphabets. Leftover alphabets which did not get inscribed by the symbolic word representations on some of the keys are grouped together and assigned to leftover keys.

### CROSS-REFERENCE TO RELATED APPLICATIONS

This application claims the benefit under 35 U.S.C. §119(a) of Korean Patent Application No. 10-2007-0079371, filed in the Korean Intellectual Property Office on Aug. 8, 2007, the entire disclosure of which is incorporated herein by reference.

### BACKGROUND

The present invention relates to a character arrangement method and a character input method in a character input device. The present invention is a technology that can be utilized in efficient character input in the field of character input devices, such as information communication devices, and a variety of electronic and machine devices requiring character input.

Exchanging text messages using an electronic device has become ubiquitous with widespread use of short text messaging on cellular phones. In existing arts for telephone-style keypads, the character arrangement method for Latin-originating alphabets is typically alphabetical sequences, often in triplets, as shown in FIG. 1. For many users of an electronic device operatively connected to a telephone-style keypad, the conventional alphabetical sequence arrangement of alphabets is counterintuitive to finding a particular alphabet rapidly or memorizing a location of the particular alphabet. Therefore, a more intuitive and natural configuration of Latin-originating alphabets arranged on a telephone-style keypad is highly desirable for rapid entry of textual messages and user interactions with electronic devices.

### SUMMARY

A method of utilizing Latin-originating alphabets as symbolic word representations on a telephone-style keypad operatively connected to an electronic device comprises steps of composing a symbolic word representation comprising a subset of the Latin-originating alphabets for a particular key on the telephone-style keypad, wherein the symbolic word representation can be an abbreviated term with a linguistic meaning, inscribing the symbolic word representation on the particular key, wherein the particular key on the telephone-style keypad typically also represents a digit between 0˜9 or a special touch-tone symbol, executing a computer software in the electronic device configured to provide a textual input program using the telephone-style keypad as an alphabet input user interface, and selecting a desired Latin-originating alphabet from the symbolic word representation inscribed on the particular key on the telephone-style keypad, wherein a selection of the desired Latin-originating alphabet is enabled by a number of sequential key presses during an operation of the textual input program.

An electronic device with a telephone-style keypad as a textual input user interface comprises a plurality of keys in the telephone-style keypad acting as the textual input user interface, wherein one or more symbolic word representations are inscribed on one or more keys using a subset of Latin-originating alphabets and wherein each symbolic word representation can be an abbreviated term with a linguistic meaning, a plurality of digits and/or special touch-tone symbol inscriptions printed on the plurality of keys in the telephone-style keypad, wherein the plurality of digits and/or special touch-tone symbol inscriptions include Arabic numerals 0˜9, an asterisk “*”, and a sharp “#”, and a computer software in the electronic device configured to provide a textual input program for the telephone-style keypad, wherein the computer software accepts a number of sequential key presses during the operation of the textual input program for selecting a desired particular Latin-originating alphabet from the one or more symbolic word representations inscribed on the one or more keys.

### BRIEF DESCRIPTION OF THE DRAWINGS

FIG. 1 shows a prior art configuration of a telephone-style keypad.

FIG. 2 shows a first example of symbolic word representations on a telephone-style keypad in accordance with an embodiment of the invention.

FIG. 3 shows a second example of symbolic word representations on a telephone-style keypad in accordance with an embodiment of the invention.

FIG. 4 shows a third example of symbolic word representations on a telephone-style keypad in accordance with an embodiment of the invention.

FIG. 5 shows a sequence of key entry by a user to input a word into an electronic device in accordance with an embodiment of the invention.

FIG. 6 shows a sequence of key entry by a user to input a word into an electronic device in accordance with an embodiment of the invention.

FIG. 7 shows a sequence of key entry by a user to input a word into an electronic device in accordance with an embodiment of the invention.

FIG. 8 shows an example of a keypad interface with a “Ten Commandments” theme from the Bible, in accordance with an embodiment of the invention.

### DETAILED DESCRIPTION

Specific embodiments of the invention will now be described in detail with reference to the accompanying figures. Like elements in the various figures are denoted by like reference numerals for consistency.

In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

In general, embodiments of the invention relate to a textual input method to an electronic device. More specifically, embodiments of the invention relate to inscribing one or more symbolic word representations to one or more keys on a telephone-style keypad operatively embedded or connected to the electronic device. Furthermore, embodiments of the invention also relate to using an abbreviated term with a linguistic meaning for a symbolic word representation inscribed to a key in the telephone-style keypad.

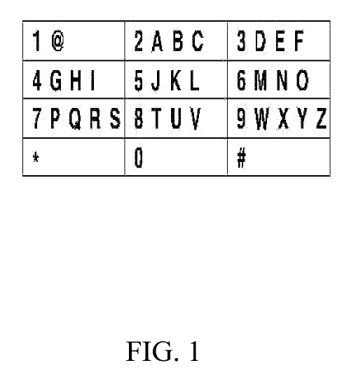

FIG. 1 shows a prior art for a telephone-style keypad interface typically found on electronic devices such as a cellular phone. In this particular prior art, each digit key (i.e. digits 0˜9) and special touch-tone symbols such as an asterisk (“*”) key and a sharp (“#”) key are laid out in three columns and four rows. Digit keys 2˜9 are also inscribed with alphabets either in triplets or quadruplets, and a digit-to-character mode selector can enable an alphabet input mode or a digit input mode. In the alphabet input mode, a particular character or alphabet can be selected for a text entry by a specific number of sequential key presses.

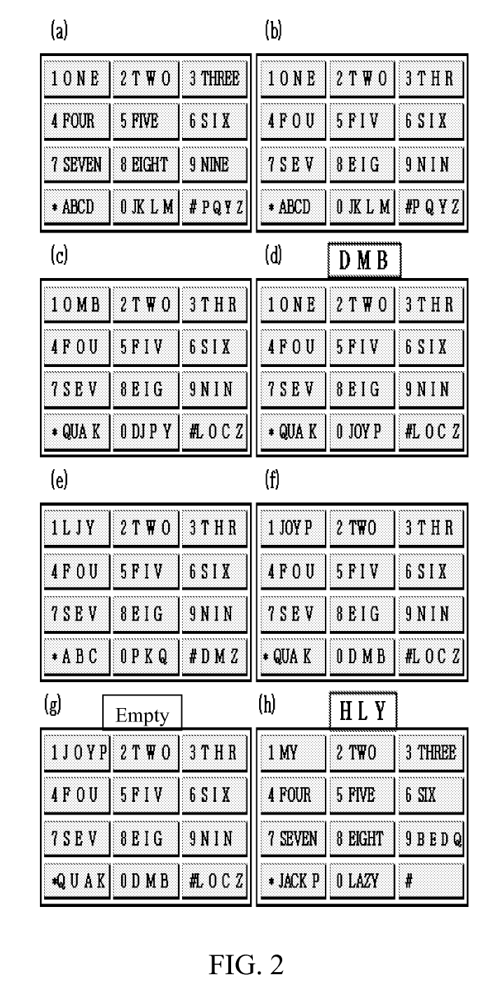

FIG. 2 shows a first example of symbolic word representations on a telephone-style keypad in accordance with an embodiment of the invention. In FIG. 2(a), alphabetized names of digits from 1˜9 are inscribed on corresponding digit keys of a telephone-style keypad, thereby presenting an intuitive and heuristic layout of English alphabets for text entry into a textual input program using the telephone-style keypad. In this particular example as shown in FIG. 2(a), characters are arranged in sequence of “1 ONE”, “2 TWO”, “3 THREE”, “4 FOUR”, “5 FIVE”, “6 SIX”, “7 SEVEN”, “8 EIGHT” and “9 NINE” on 9 digit keys. Because there are 12 characters not appearing in the English spelling of the alphabetized names for digits 1˜9, the “leftover” alphabets (i.e. unrepresented remaining alphabets in the English language), namely, ABCD, JKLM and PQYZ are assigned to an asterisk (“*”) key, a digit “0” key, and a sharp (“#”) key, respectively. In a telephone-style keypad configuration as shown in FIG. 2(a), the “* ABCD” key is located on a left corner of the bottommost line, “0 JKLM” key is located in the middle of the bottommost line, and “# PQYZ” key is located on a right corner of the bottommost line.

FIGS. 2(b), (c) and (d) show embodiments in which three-letter abbreviations for alphabetized digits for digits 1˜9 are inscribed on digit keys 1˜9. This character arrangement includes a process of assigning a three-letter abbreviation per digit key for digit keys 1˜9 to constitute nine keys on a telephone-style keypad in the following manner: “1 ONE”, “2 TWO”, “3 THR”, “4 FOU”, “5 FIV”, “6 SIX”, “7 SEV”, “8 EIG”, and “9 NIN”. As explained previously for character configurations in FIG. 2(a), any “leftover” alphabets not used in the nine keys above can be combined intuitively (e.g. “ABCD”, “JKLM”, and “PQYZ”, or “QUAK”, “DJPY”, and “LOCZ”) and inscribed on remaining digit keys or special touch-tone symbols. FIG. 2(b) keypad configuration is the applicant's preferred best mode for the present invention.

A key feature of the present invention is that alphabets or characters can appear on the keypad multiple times (i.e. redundantly) to enable a more intuitive and user-friendly text-input interface. Therefore, the present invention can be used to place the most commonly used alphabets for text entry on a multiple number of keys for easier entry by a user. It is also an intended goal of this invention to make a majority of combination of alphabets appearing on telephone-style keypads to present a linguistically-meaningful picture for heuristic and intuitive text entry by the user.

In case of FIGS. 2(b), 2(c), and 2(d), there are 12 “leftover” alphabets which are not used in digit keys 1˜9. It is important to note that the present invention breaks away from a conventional arrangement of alphabets on a telephone-style keypad, in which the 26 English alphabets is only used once. The present invention allows redundant arrangement of the alphabets for easier entry of commonly-used vowels and consonants. In this redundant arrangement of the alphabets, at least one alphabet of the vowels in the English alphabet (e.g. a, e, i, o, and u) can be arranged redundantly two to twelve times in a telephone-style keypad, and at least one alphabet of the consonant (i.e. the remaining characters in the English alphabets) can be arranged redundantly two to twelve times in the telephone-style keypad.

There are fundamental advantages when redundant characters are provided in a heuristically and linguistically meaningful way to a user on a telephone-style keypad. The user is likely to have a quicker learning curve to memorize location of each letter and readily apply the heuristic arrangement of alphabets on the telephone-style keypad for rapid text entry. For example, if a user intends to enter text “tv”, one of 3 numeric keys of “2 TWO”, “3 THREE” and “8 EIGHT” can be used in order to input “t” in FIG. 2(a).

In one embodiment of the present invention, a symbolic word representation can be formed with 3 letters for a particular key on a telephone-style keypad. For instance, only the first three letters may be inscribed on some digit keys, as found in “3 THR”, “4 FOU”, “5FIV”, “7 SEV”, “8 EIG” and “9 NIN”, shown in FIG. 2(b), FIG. 2(c), FIG. 2(d), FIG. 2(e), FIG. 2(f), and FIG. 2(g). Using three-letter or four-letter abbreviated terms, typically with linguistic meanings, is sufficient to construct symbolic word representations on a key layout of the telephone-style keypad. Redundant alphabets may be inserted or omitted at a keypad designer's discretion and the key layout generally includes all 26 English letters, even though some letters are designed to appear more than once.

In one embodiment of the present invention, the user entry of text is typically executed by a computer software in the electronic device which provides a textual input program using a telephone-style keypad as an alphabet-input user interface. Because each key on the telephone-style keypad typically has more than one letter or digit, a character/digit mode selection method is provided to the user and a selection of a desired alphabet is enabled by a number of sequential key presses during an operation of the textual input program.

FIG. 2(b) shows an embodiment of the present invention in which 1˜9 digit keys each comprises three letters for alphabetized abbreviated name. Leftover alphabets not appearing on 1˜9 digit keys are arranged in remaining keys, as shown in a “* ABCD” key, a “0 JKLM” key and a “# PQYZ” key. FIG. 2(c) shows a slightly modified embodiment of FIG. 2(b). In this embodiment, if a user's initial is OMB, OMB can be inscribed to a digit “1” key as “1 OMB” via custom-order manufacturing. Further, keys “* QUAK”, “0 DJPY”, and “# LOCZ” are arranged and inscribed to the bottom three keys of FIG. 2(c). They could represent symbolic word representations of specific persons or functions of the keys. The “* QUAK” key can also be used as a vibration mode switch in mobile phones.

FIG. 2(d) shows an embodiment of the present invention, in which “DMB”, represents an initial of a specific person and can act as an additional key to the telephone-style keypad. Presumably, a user can custom-order an electronic device from a manufacturer to print any desired abbreviated terms or symbolic word representations on one or more keys on a telephone-style keypad operatively connected to the electronic device. In most applications, the keypad layout will contain a comprehensive set of Latin-originating alphabets for one particular language (e.g. English, French, German, Spanish, or any other Romantic languages), but an alphabet can appear more than once on the keypad layout. The possibility of redundant inscription of alphabets is one of the distinguishing aspects of the present invention from existing keypad configurations.

Similarly, in the digit “1” key of FIG. 2(e), a person's initial “LJY” is inscribed and a complete set of English alphabet is still presented for text entry to the user with intentional character redundancies. Presumably, companies and marketers can inscribe a corporate initial or any other symbolic word representation for marketing an electronic device such as a cellular phone. For example, if “BMW” is arranged in a particular key on the keypad, it may be called a “BMW phone” for marketing purposes.

FIG. 2(f) shows an embodiment of the present invention in which alphabetized abbreviated digit names are arranged in numeric keys 2˜9 and the remaining keys are used for symbolic word representations (e.g. “JOY P”, “DMB”) or leftover alphabet inscriptions (e.g. “QUAK”, “LOCZ”).

FIG. 2(g) shows an embodiment of the present invention in which an additional key (i.e. a key labeled “empty” in the drawing) at the top is empty. In one case of marketing applications, a user of an electronic device containing a telephone-style keypad can custom order the electronic device to contain his or her own initials for the additional key (i.e. the key labeled “empty” in the drawing).

FIG. 2(h) shows a modified embodiment of FIG. 2(a) in accordance with an embodiment of the present invention. In this particular example, “MY” is inscribed on a digit “1” key. “BEDQ” is inscribed on a digit “9” key. “JACK P” is inscribed on an asterisk (“*”) key. “LAZY” is inscribed on a digit “0” key. Additionally, a sharp (“#”) key with no alphabet inscriptions is configured as a reverse-order input key. The applicant defines this particular embodiment as “MY PHON” embodiment.

In the “MY PHON” embodiment of the present invention, four to five alphabets are inscribed on many keys (i.e. “3 THREE”, “4 FOUR”, “5 FIVE”, “7 SEVEN”, “8 EIGHT”, “9 BEDQ”, “* JACK P”, “0 LAZY”), which could be considered an excessive number of alphabets per key for forward-order entry. An alphabet entry into a textual input program using a telephone-style keypad generally requires a number of sequential key presses during an operation of the textual input program. Therefore, by providing means of reverse-order entry, with a forward-order/reverse-order selector represented by the sharp (“#”) key in the MY PHON embodiment, a user can minimize the number of sequential key presses to select a desired alphabet, even if it appears towards the end of a long string of alphabets (e.g. four to five alphabets per key as shown in this example).

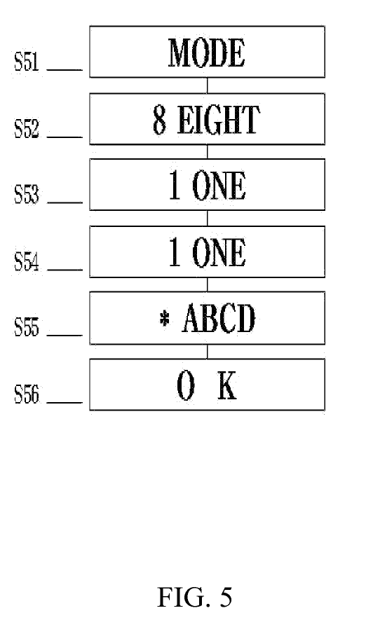

FIG. 5 shows a sequence of key entry by a user to enter a word into an electronic device in accordance with an embodiment of the invention corresponding to a telephone-style keypad of FIG. 2(a). In this particular example, several steps occur to enter a word “good” into the electronic device. A first optional step (S51) is resetting a text-entry mode to the character mode. A second step (S52) is entering the alphabet ‘g’ by pressing the “8 EIGHT” key three times. A third step (S53) is entering the alphabet ‘o’ by pressing the “1 ONE” key once. A fourth step (S54) is entering another ‘o’ by pressing the “1 ONE” key once. A fifth step (S55) is entering the alphabet ‘d’ by pressing the “* ABCD” key five times. Lastly, a sixth step (S56) is confirming the entered text for further execution by a computer software, resulting in an entered text string of the word “good”.

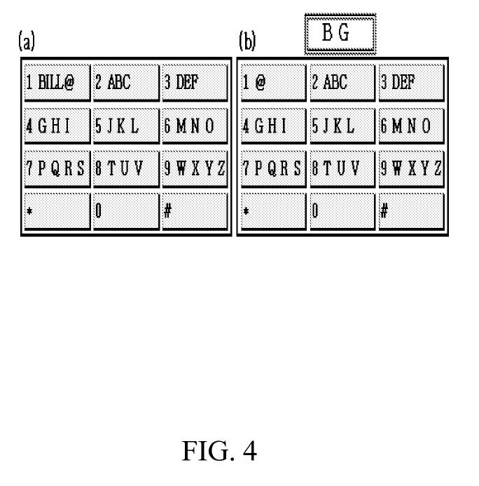

FIGS. 4(a) and (b) show embodiments of the present invention which are applied to an existing common layout of alphabets on a telephone-style keypad. In FIG. 4(a), a person's name “BILL” is inscribed on a digit “1” key but still maintains conventional keypad configuration for all 12 keys on the telephone-style keypad. In one application of this embodiment, a user can personalize his or her own cellular phone by custom-ordering a handset unit from a manufacturer with a request to inscribe personalized names, initials, or other symbolic word representations.

In FIG. 4(b), a person's initial “BG” is implemented as an additional key configured to accommodate redundant text entry into a textual input program. This embodiment maintains all of the existing keypad layouts and simply adds the additional key for personalization of an electronic device connected to a telephone-style keypad, such as a cellular phone.

Redundancies of alphabets are pervasive in the present invention for easier finding and entry of alphabets from a telephone-style keypad. In FIG. 2(g), vowel ‘e’ is used twice. Vowel ‘o’ is used four times. Furthermore, vowel ‘i’ is used four times and vowel ‘V’ is used twice. In this example, consonants ‘t’, ‘n’, ‘f’, and ‘s’ are used twice.

The vowels, such as ‘A’, ‘E’, ‘I’, ‘O’ and ‘U’ which can be pronounced easily by human's vocal chord in any Latin-originating language, frequently occur and therefore important. In FIG. 2(h), a frequently-occurring vowel, ‘e’, is designed to appear seven times in a telephone-style keypad. Vowel ‘o’ is used twice. Vowel ‘i’ is used three times and vowel ‘A’ is used twice.

Furthermore, the present invention allows the use of a reverse-order text entry to reduce the number of key presses. For example, if ‘e’ is input in the “3 THREE” key, ‘e’ can be selected by pressing the key four times sequentially in a forward-order text entry mode, but in a reverse-order text entry mode, ‘e’ can be entered into an electronic device by pressing the key only once. A key for selecting the reverse-order input mode can be set to the special symbol keys such as the asterisk (‘*’) key or the sharp (‘#’) key. Alternatively, an additional dedicated key can be used.

A preferred embodiment has the forward-order text entry mode as a default. Whenever a user selects a reverse-order text entry mode, the default forward-order text entry renews after an end confirmation of a desired reverse-order text entry.

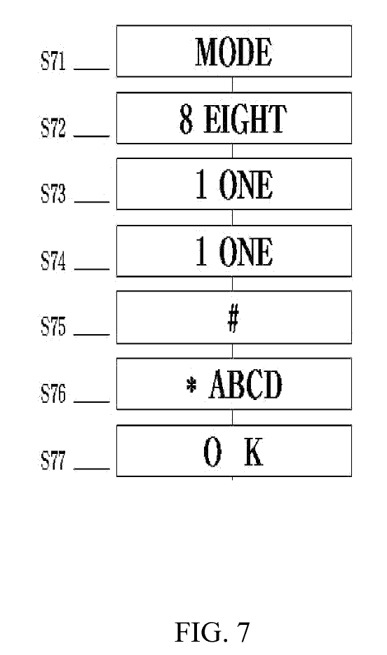

FIG. 7 shows a sequence of key entry by a user to input a word “good” into an electronic device in a reverse-order input mode in accordance with an embodiment of the invention corresponding to a keypad configuration of FIG. 2(a). In one embodiment of the invention, when the electronic device is initially set to the forward-order input mode, a first step (S71) optionally sets the alphabet/numeric selector to the lower-case alphabet mode. A second step (S72) enters the first letter ‘g’ by pressing the “8 EIGHT” key three times. A third step (S73) enters the second letter ‘o’ by pressing the “1 ONE” key once. A fourth step (S74) enters the fourth letter ‘o’ by pressing the “1 ONE” key once. A fifth step (S75) then switches the forward-order input mode to the reverse-order input mode by pressing the sharp (‘#’) key in order to enter ‘d’ starting from the right side of a text string. Then, a sixth step (S76) enters ‘d’ by pressing the “* ABCD” key once, and a seventh step (S77) processes the entered text string when the user confirms text entry.

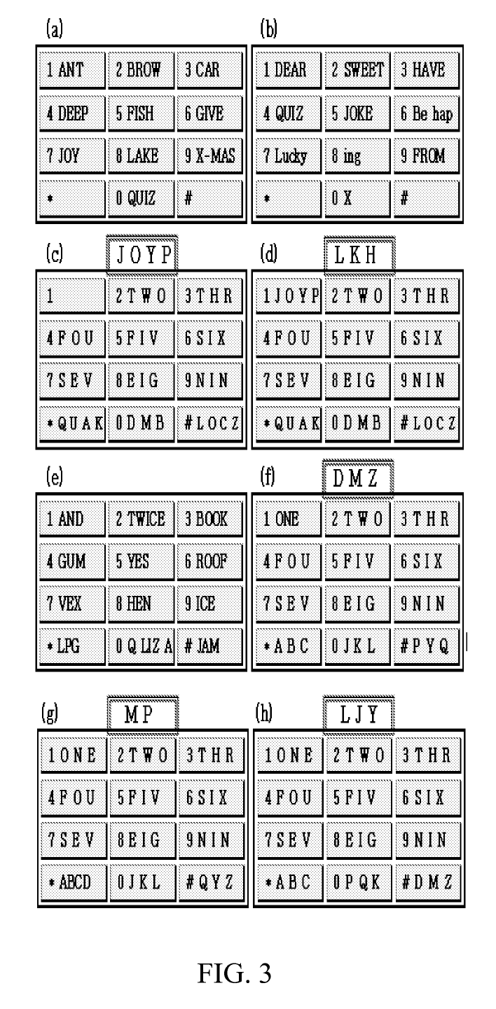

FIG. 3(a) shows another embodiment of the present invention, with symbolic word representations assigned to some keys on a telephone-style keypad. In this particular example, symbolic word representations “ANT”, “BROW”, “CAR”, “DEEP”, “FISH”, “GIVE”, “JOY”, “LAKE”, “X-MAS”, “QUIZ” are assigned to the 1, 2, 3, 4, 5, 6, 7, 8, 9, 0 keys, respectively, which covers all 26 English alphabets with some redundancies.

FIG. 3(a) shows another embodiment of the present invention, with symbolic word representations assigned to some keys on a telephone-style keypad. In this particular example, symbolic word representations “DEAR”, “SWEET”, “HAVE”, “JOKE”, “Be hap”, “SWEET”, “Lucky”, “ING”, “FROM” are arranged in the 1, 2, 3, 4, 5, 6, 7, 8, 9 keys, respectively. Digit “0” key is assigned the alphabet “x”. In this example, a cellular phone which uses this keypad configuration may be called a “Lucky phone” because digit “7” is inscribed with the symbolic word representation “Lucky”.

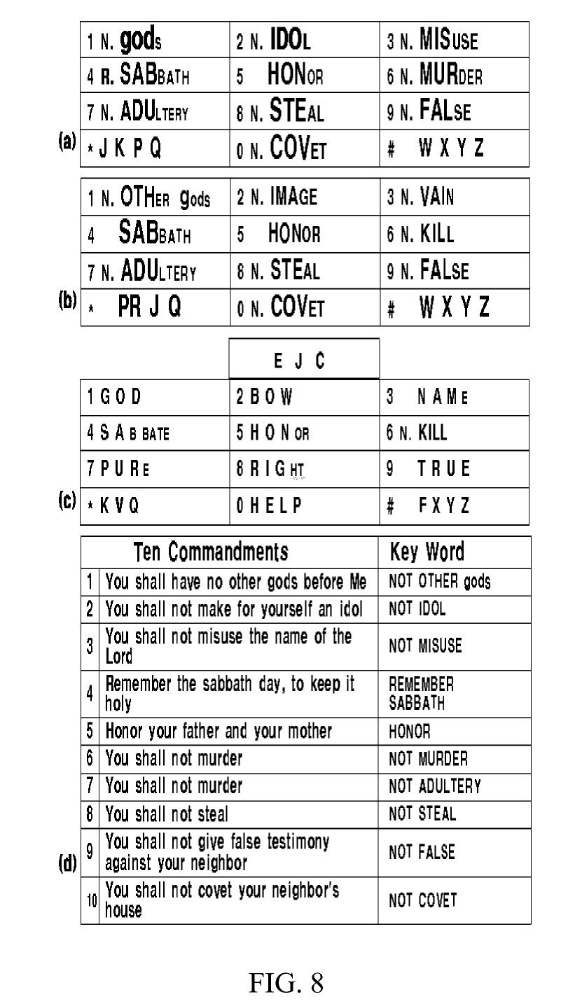

FIG. 8 shows an embodiment of the present invention providing symbolic word representations for the Ten Commandments of the Bible on a telephone-style keypad.

FIG. 8(d) illustrates the Ten Commandments and their corresponding keywords to be used on the telephone-style keypad. This is for the purpose of printing the keyword since the entire Ten Commandments cannot be printed in the keys. FIG. 8(a) shows an embodiment employing the corresponding keywords as shown in FIG. 8(d). FIG. 8(b) and (c) are modifications of the keyword on the basis of meaning. In this particular example, only upper case alphabets are used to symbolize the Ten Commandments. Alphabets not included in the Ten Commandments keywords are assigned to special touch-tone symbols such as an asterisk (“*”) key or a sharp (“#”) key.

In FIG. 8(c), an additional key, “EJC,” at the top denotes the first letters of “ETERNAL”, “JESUS”, and “COMMANDMENTS”. “N” in the digit “1” key denotes “NO”, and the remaining “N′” s are abbreviations for “NOT”.

Furthermore, in the present invention, when letters to be input are arranged as words in the key, they can be input at once by reducing the number of pressing the key. This input method is also called a “key-all input method”. For example, if it is sought to input “have”, “have” can generally be input by pressing the key four times. However, in the key-all input method, “have” can be input by pressing the key once or twice.

The “*” key or the “#” key can be set as a key for selecting the “key-all input method” mode, or an additional dedicated key can be produced and used. In this case, the “key-all input method” mode can be input at once by setting a pressed time.

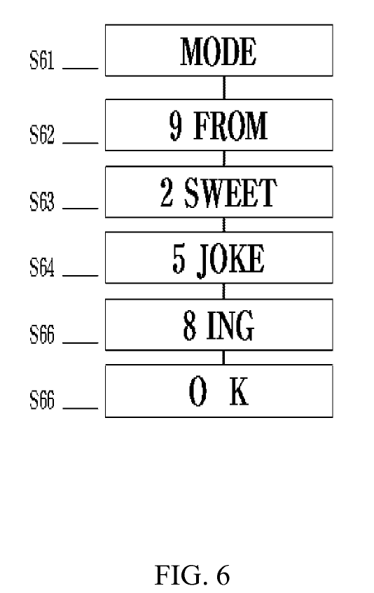

FIG. 6 shows a sequence of key entry by a user to input a word into an electronic device with a telephone-style keypad in a particular configuration as shown in FIG. 3(b). In order to enter a text, “from son,” according to the method of the present invention, the first step (S61) is setting the alphabet/numeric selector to a lower-case alphabet mode. A second step (S62) is entering the first alphabet “from” in one batch by pressing a “9 FROM” key for a predetermined time period in accordance with the “key-all input method”. A third step (S63) is entering an alphabet ‘s’ by pressing a “2 SWEET” key once. A fourth step (S64) is entering an alphabet ‘o’ by pressing a “5 JOKE” key twice. A fifth step (S65) is entering an alphabet ‘n’ by pressing a “8 ING” key twice. Lastly, a sixth step (S66) processes the entered text string “from son” when the user confirms text entry, typically with a confirmation key for “OK”.

FIG. 3(c) shows a slight modification of FIG. 2(g) in which the symbolic word representations on digit “1” key and on an additional top key are changed. In this embodiment, a person's favorite abbreviated term with a linguistic meaning is placed on the additional top key inscribed with alphabets “JOYP”.

FIG. 3(d) shows another embodiment of the present invention with a top additional key with a person's initial, “LKH”. FIG. 3(e) shows another embodiment of the present invention with digit “0” key having a theme of “Queen Elizabeth”.

FIG. 3(f) shows another embodiment of the present invention. In this embodiment, an additional key on the top of the keypad is inscribed with an initial “DMZ” (de-militarized zone).

FIG. 3(g) shows another embodiment of the present invention. In this embodiment, an additional key on the top of the keypad is inscribed with alphabets “MP”. The “MP” key can be used as an alphabet-entry button for a text input while having a secondary function to control an MP3 player.

FIG. 3(h) shows another embodiment of the present invention. In this embodiment, an additional key on the top of the keypad is inscribed with alphabets “LJY,” which may be a name of a person.

The present invention enables a user to enter texts into a textual input program quickly, intuitively, and heuristically by creating symbolic word representations on at least some keys on a telephone-style keypad. By allowing multiple inscriptions of alphabets on the telephone-style keypad, the present invention provides an added efficiency and convenience of entering a frequently-used alphabet from a multiple number of keys.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A method of utilizing Latin-originating alphabets as symbolic word representations on a telephone-style keypad operatively connected to an electronic device, the method comprising:
composing a symbolic word representation comprising a subset of the Latin-originating alphabets for a particular key on the telephone-style keypad, wherein the symbolic word representation can be an abbreviated term with a linguistic meaning;
inscribing the symbolic word representation on the particular key, wherein the particular key on the telephone-style keypad typically also represents a digit between 0˜9 or a special touch-tone symbol;
executing a computer software in the electronic device configured to provide a textual input program using the telephone-style keypad as an alphabet input user interface; and
selecting a desired Latin-originating alphabet from the symbolic word representation inscribed on the particular key on the telephone-style keypad, wherein a selection of the desired Latin-originating alphabet is enabled by a number of sequential key presses during an operation of the textual input program.

2. The method of claim 1, wherein the Latin-originating alphabets are comprehensively but in some cases redundantly represented by a complete set of keys on the telephone-style keypad.

3. The method of claim 2, wherein the Latin-originating alphabets cover English letters A˜Z and the textual input program provides a method to select lower or upper case alphabets.

4. The method of claim 1, wherein the symbolic word representation inscribed on the particular key on the telephone-style keypad is an alphabetized abbreviated name of the digit between 0˜9 or the special touch-tone symbol also inscribed on the particular key.

5. The method of claim 1, wherein the symbolic word representation inscribed on the particular key on the telephone-style keypad is an abbreviated term for one of the Ten Commandments from the Bible.

6. The method of claim 1, wherein the symbolic word representation inscribed on the particular key on the telephone-style keypad is a desired abbreviated term requested by a particular user who custom-orders the electronic device from a manufacturer to print the desired abbreviated term on the particular key on the telephone-style keypad.

7. The method of claim 2, further comprising a step of inscribing one or more leftover alphabets not represented by a plurality of symbolic words on a plurality of keys on one or more leftover keys on the telephone-style keypad.

8. The method of claim 4, wherein the step of inscribing the symbolic word representation on the particular key for the alphabetized abbreviated name of the digit between 1˜9 comprises one of following combinations:
“1 ONE”, “2 TWO”, “3 THR”, “4 FOU”, “5 FIV”, “6 SIX”, “7 SEV”, “8 EIG”, or “9 NIN”.

9. The method of claim 8, further comprising a step of inscribing “ABCD”, “JKLM”, and/or “PQYZ” on a remaining key on the telephone-style keypad, wherein the remaining key is a “*” key, a “#” key, or a “0” key.

10. The method of claim 1, wherein the step of inscribing the symbolic word representation on the particular key for the alphabetized abbreviated name of the digit between 0˜9 comprises one of following combinations: ANT, BROW, CAR, DEEP, FISH, GIVE, JOY, LAKE, XMAS, or QUIZ.

11. The method of claim 1, wherein the step of inscribing the symbolic word representation on the particular key for the alphabetized abbreviated name of the digit between 0˜9 comprises one of following combinations: DEAR, SWEET, HAVE, QUIZ, JOKE, BE HAP, LUCKY, ING, FROM, or X.

12. An electronic device with a telephone-style keypad as a textual input user interface, the electronic device comprising:
a plurality of keys in the telephone-style keypad acting as the textual input user interface, wherein one or more symbolic word representations are inscribed on one or more keys using a subset of Latin-originating alphabets and wherein each symbolic word representation can be an abbreviated term with a linguistic meaning;
a plurality of digits and/or special touch-tone symbol inscriptions printed on the plurality of keys in the telephone-style keypad, wherein the plurality of digits and/or special touch-tone symbol inscriptions include Arabic numerals 0˜9, an asterisk “*”, and a sharp “#”; and
a computer software in the electronic device configured to provide a textual input program for the telephone-style keypad, wherein the computer software accepts a number of sequential key presses during the operation of the textual input program for selecting a desired particular Latin-originating alphabet from the one or more symbolic word representations inscribed on the one or more keys.

13. The electronic device of claim 12, wherein the one or more symbolic word representations inscribed on the one or more keys sometimes present redundant Latin-originating alphabets.

14. The electronic device of claim 13, wherein the Latin-originating alphabets cover English letters A˜Z and the textual input program provides a method to select lower or upper case alphabets.

15. The electronic device of claim 12, wherein the one or more symbolic word representations inscribed on the one or more keys using the subset of Latin-originating alphabets are alphabetized abbreviated names of the plurality of digits between 0˜9 and/or the special touch-tone symbol inscriptions.

16. The electronic device of claim 12, wherein the one or more symbolic word representations inscribed on the one or more keys using the subset of Latin-originating alphabets are abbreviated terms for some of the Ten Commandments from the Bible.

17. The electronic device of claim 12, wherein the one or more symbolic word representations inscribed on the one or more keys using the subset of Latin-originating alphabets are desired abbreviated terms requested by a particular user who custom-orders the electronic device from a manufacturer to print the desired abbreviated terms on the one or more keys.

18. The electronic device of claim 13, further comprising one or more leftover alphabets inscribed on one or more leftover keys in the telephone-style keypad, wherein the leftover alphabets are not represented by the one or more symbolic words inscribed on the one or more keys.

19. The electronic device of claim 15, wherein the one or more symbolic word representations on the one or more keys for the alphabetized abbreviated names of the plurality of digits between 0˜9 and/or the special touch-tone symbol comprise some or all of following combinations:
“1 ONE”, “2 TWO”, “3 THR”, “4 FOU”, “5 FIV”, “6 SIX”, “7 SEV”, “8 EIG”, or “9 NIN”.

20. The electronic device of claim 19, further comprising additional keys inscribing “ABCD”, “JKLM”, and/or “PQYZ”, wherein the additional keys are “*” key, a “#” key, and a “0” key.
